(19) United States
(12) Patent Application Publication
(10) Pub. No.: US 2026/0371709 A1
(43) Pub. Date: Nov. 19, 2026

(54) SEMICONDUCTOR DEVICE AND MANUFACTURING METHOD THEREOF

(71) Applicant: INSTITUTE OF MICROELECTRONICS, CHINESE ACADEMY OF SCIENCES, Beijing (CN)

(72) Inventors: Junshuai CHAI, Beijing (CN); Xiaolei WANG, Beijing (CN); Yong DU, Beijing (CN); Hao XU, Beijing (CN); Jun LUO, Beijing (CN); Wenwu WANG, Beijing (CN); Tianchun YE, Beijing (CN)

(73) Assignee: INSTITUTE OF MICROELECTRONICS, CHINESE ACADEMY OF SCIENCES, Beijing (CN)

(21) Appl. No.: 19/283,616

(22) Filed: Jul. 29, 2025

(30) Foreign Application Priority Data
May 13, 2025 (CN) 202510613071.7

(51) Int. Cl. H10D 84/83; H10D 84/01

(52) U.S. Cl. CPC H10D 84/83138; H10D 84/0142; H10D 84/016; H10D 84/837

(57) ABSTRACT

The present disclosure provides a semiconductor device, including: a substrate; and a first field-effect transistor and a second field-effect transistor that are respectively stacked on the substrate and are mirror-symmetrical relative to a first plane extending in a vertical direction and a first horizontal direction, where the first field-effect transistor and the second field-effect transistor each include: a first source/drain portion, a channel portion and a second source/drain portion that are sequentially stacked on the substrate, and a gate stack located on two opposite sides of the channel portion in the first horizontal direction, where the gate stack includes a first gate stack located on a side of the channel portion close to the first plane, and a second gate stack located on a side of the channel portion away from the first plane and at least partially surrounded by the channel portion in the first horizontal direction.

### CROSS REFERENCE TO RELATED APPLICATION

This application claims priority to Chinese Patent Application No. 202510613071.7, filed on May 13, 2025, the entire content of which is incorporated herein in its entirety by reference.

### TECHNICAL FIELD

The present disclosure relates to a field of semiconductor technology, and in particular to a semiconductor device with a multi-threshold voltage regulation and a manufacturing method thereof.

### BACKGROUND

In the manufacturing of a complementary metal-oxide semiconductor and a high-density logic and memory chip at the 2 nm node and below, a vertical-channel semiconductor device has been widely used due to its higher integration degree of freedom in a vertical direction.

In a process of implementing the concept of the present disclosure, the inventors found that a film thickness regulation of a gate metal work function layer in the related art is difficult to be applied to the vertical-channel semiconductor device.

### SUMMARY

In view of this, the present disclosure provides a semiconductor device and a manufacturing method thereof.

An aspect of the present disclosure provides a semiconductor device, including:
a substrate; and a first field-effect transistor and a second field-effect transistor that are respectively stacked on the substrate and are mirror-symmetrical relative to a first plane extending in a vertical direction and a first horizontal direction, where the first field-effect transistor and the second field-effect transistor each include: a first source/drain portion, a channel portion and a second source/drain portion that are sequentially stacked on the substrate, and a gate stack located on two opposite sides of the channel portion in the first horizontal direction, where the gate stack includes a first gate stack located on a side of the channel portion close to the first plane, and a second gate stack located on a side of the channel portion away from the first plane and at least partially surrounded by the channel portion in the first horizontal direction.

According to embodiments of the present disclosure, the channel portion includes a first portion located between the first gate stack and the second gate stack, a second portion located between the second gate stack and the first source/drain portion, and a third portion between the second gate stack and the second source/drain portion.

According to embodiments of the present disclosure, the first portion of the channel portion extends in the vertical direction, and the second portion and the third portion of the channel portion extend in a second horizontal direction intersecting the first horizontal direction.

According to embodiments of the present disclosure, respective channel portions of the first field-effect transistor and the second field-effect transistor are each U-shaped, and have openings that are opposite to each other or reversed.

According to embodiments of the present disclosure, in the vertical direction, an end portion of the second portion of the channel portion in the first horizontal direction and an end portion of the third portion of the channel portion in the first horizontal direction are aligned with a sidewall of the second gate stack in the first horizontal direction.

According to embodiments of the present disclosure, respective first gate stacks or respective second gate stacks of the first field-effect transistor and the second field-effect transistor are opposite to each other.

According to embodiments of the present disclosure, when different operating voltages are applied to the first gate stack and the second gate stack, a multi-threshold voltage regulation of the semiconductor device is achieved.

Another aspect of the present disclosure provides a method of manufacturing a semiconductor device, including:
sequentially forming a first film layer and a mandrel on a substrate, where the first film layer includes a first source/drain layer, a sacrificial gate on the first source/drain layer and a second source/drain layer on the sacrificial gate, the mandrel includes a first sacrificial layer and an insulating layer located on the first sacrificial layer, and the mandrel is recessed inward relative to the first film layer in both a first horizontal direction and a second horizontal direction intersecting the first horizontal direction; forming a second sacrificial layer and a third sacrificial layer on an upper surface of the first film layer and an outer surface of the mandrel, where the third sacrificial layer is recessed inward relative to the second sacrificial layer in both the first horizontal direction and the second horizontal direction; vertically etching the second sacrificial layer and the first film layer, until an etched first film layer, an etched second sacrificial layer and the third sacrificial layer are aligned in a vertical direction; horizontally etching the sacrificial gate, so that an etched sacrificial gate is recessed inward relative to the first source/drain layer and the second source/drain layer in both the first horizontal direction and the second horizontal direction; sequentially forming a channel layer and an isolation layer on a periphery of the first film layer, a periphery of the second sacrificial layer and a periphery of the third sacrificial layer; grinding an upper surface of the isolation layer, an upper surface of the channel layer and an upper surface of the insulating layer, until an upper surface of the first sacrificial layer is exposed; removing the first sacrificial layer and etching the first film layer, so that the isolation layer forms a groove with an upper surface of the substrate, where the groove is aligned with the first sacrificial layer in the vertical direction; removing the isolation layer to expose the channel layer, and depositing a gate stack on an outer side of the channel layer, on an upper surface of the second source/drain layer and inside the groove; removing part of the gate stack, and leaving only an outer gate stack on a side of the channel layer away from the groove and an inner gate stack on a side of the channel layer close to the groove between the first source/drain layer and the second source/drain layer, so as to obtain an annular double-gate device; and etching off both ends of the annular double-gate device to obtain a first field-effect transistor and a second field-effect transistor, where an etched inner gate stack is used as a first gate stack of the first field-effect transistor and the second field-effect transistor, and an etched outer gate stack is used as a second gate stack of the first field-effect transistor and the second field-effect transistor.

According to embodiments of the present disclosure, the sequentially forming a first film layer and a mandrel on a substrate includes: forming, on the substrate, the first film layer and a second film layer stacked on the first film layer, where the second film layer includes the first sacrificial layer and the insulating layer located on the first sacrificial layer; and vertically etching the second film layer to obtain the mandrel.

According to embodiments of the present disclosure, a material of the insulating layer is the same as a material of the second sacrificial layer and a material of the third sacrificial layer and is different from a material of the first sacrificial layer, so that an etching rate of the insulating layer is greater than an etching rate of the first sacrificial layer.

### BRIEF DESCRIPTION OF THE DRAWINGS

The above and other objectives, features, and advantages of the present disclosure will be more apparent through the following description of embodiments of the present disclosure with reference to accompanying drawings, in which:

FIG. 1A schematically shows a cross-sectional view of a semiconductor device according to embodiments of the present disclosure.

FIG. 1B schematically shows a three-dimensional schematic diagram of a semiconductor device according to embodiments of the present disclosure.

FIG. 2 schematically shows a flowchart of a method of manufacturing a semiconductor device according to embodiments of the present disclosure.

FIG. 3 to FIG. 18 schematically show cross-sectional views of structures obtained after performing part of processes in the method shown in FIG. 2.

### DETAILED DESCRIPTION OF EMBODIMENTS

Embodiments of the present disclosure will be described with reference to the accompanying drawings. However, it should be understood that these descriptions are merely exemplary and are not intended to limit the scope of the present disclosure. In the following detailed descriptions, for the convenience of explanation, many specific details are set forth to provide a comprehensive understanding of embodiments of the present disclosure. However, it is obvious that one or more embodiments may be implemented without these specific details. In addition, in the following descriptions, descriptions of well-known structures and technologies are omitted to avoid unnecessarily obscuring the concept of the present disclosure.

Terms used herein are only intended to describe specific embodiments and are not intended to limit the present disclosure. Terms “include”, “comprise”, “contain”, etc. used herein indicate the presence of the described features, steps, operations and/or components, but do not exclude the presence or addition of one or more other features, steps, operations and/or components.

All terms (including technical and scientific terms) used herein have meanings generally understood by those of ordinary skilled in the art, unless otherwise defined. It should be noted that the terms used herein should be interpreted as having the meaning consistent with the context of the present disclosure, and should not be interpreted in an idealized or overly rigid manner.

Various schematic structural diagrams according to embodiments of the present disclosure are shown in the accompanying drawings. The drawings are not drawn to scale. Some details are enlarged and some details may be omitted for clarity of presentation. Shapes of the various regions, layers as well as a relative size and a positional relationship thereof shown in the drawings are only exemplary. In practice, there may be deviations due to manufacturing tolerances or technical limitations, and those skilled in the art may additionally design regions/layers with different shapes, sizes, and relative positions according to actual needs. In the context of the present disclosure, when a layer/element is referred to as being located “on” another layer/element, the layer/element may be directly on the another layer/element, or there may be an intermediate layer/element therebetween. In addition, if a layer/element is located “on” another layer/element in one orientation, the layer/element may be located “under” the another layer/element when the orientation is reversed.

In a process of implementing the inventive concept of the present disclosure, the inventors found that a vertical-channel semiconductor device may increase a design space of gate and source/drain, thereby reducing an occupied area of the device, may relatively easy to achieve vertical stacking among multilayer devices and further increase an integration density through a corresponding design of a wiring method, and thus may have more integration degree of freedom in a vertical direction.

A multi-threshold voltage (Multi-VT) regulation of the semiconductor device is one of key technologies to achieve a high-performance and low-power circuit. Therefore, a multi-threshold technology may have certain advantages for a complementary metal-oxide semiconductor and a high-density logic and memory chip. However, for the vertical-channel device, a film thickness regulation of a gate metal work function layer in the related art is difficult to adapt to a three-dimensional structure of the vertical channel and a diversified channel material.

In view of this, embodiments of the present disclosure provide a semiconductor device, including:
a substrate; and a first field-effect transistor and a second field-effect transistor that are respectively stacked on the substrate and are mirror-symmetrical relative to a first plane extending in a vertical direction and a first horizontal direction, where the first field-effect transistor and the second field-effect transistor each include: a first source/drain portion, a channel portion and a second source/drain portion that are sequentially stacked on the substrate, and a gate stack located on two opposite sides of the channel portion in the first horizontal direction, where the gate stack includes a first gate stack located on a side of the channel portion close to the first plane, and a second gate stack located on a side of the channel portion away from the first plane and at least partially surrounded by the channel portion in the first horizontal direction.

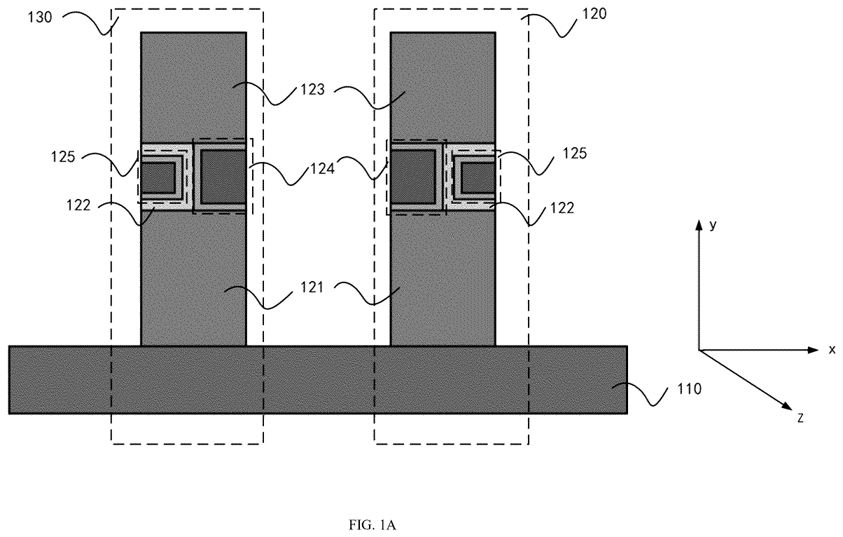

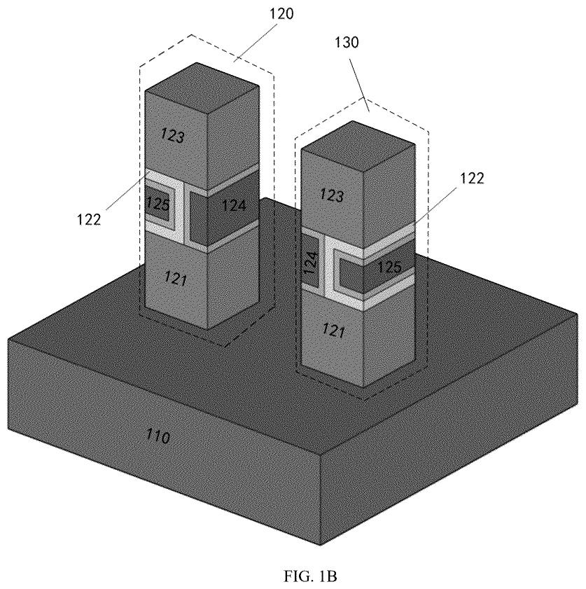

FIG. 1A schematically shows a cross-sectional view of a semiconductor device according to embodiments of the present disclosure.

FIG. 1B schematically shows a three-dimensional schematic diagram of a semiconductor device according to embodiments of the present disclosure.

As shown in FIG. 1A and FIG. 1B, the semiconductor device includes a substrate 110 and a first field-effect transistor 120 and a second field-effect transistor 130 located on the substrate 110. The first field-effect transistor 120 and the second field-effect transistor 130 are mirror-symmetrical relative to a first plane extending in a vertical direction (y direction in FIG. 1A) and a first horizontal direction (z direction in FIG. 1A). The first field-effect transistor 120 and the second field-effect transistor 130 each include: a first source/drain portion 121, a channel portion 122 and a second source/drain portion 123 that are sequentially stacked on the substrate 110, and a gate stack located on two opposite sides of the channel portion 122 in the first horizontal direction (z direction in FIG. 1A), where the gate stack includes a first gate stack 124 located on a side of the channel portion 122 close to the first plane, and a second gate stack 125 located on a side of the channel portion 122 away from the first plane and at least partially surrounded by the channel portion 122 in the first horizontal direction.

According to embodiments of the present disclosure, the substrate 110 may include Bulk-Si or silicon-on-insulator (SOI), which will not be limited here. The substrate further includes a shallow trench isolation (not shown) to define an active region of the current device, thereby isolating adjacent devices. The shallow trench isolation may include an oxide (e.g., silicon oxide). In addition to a shallow trench isolation process, an LOCOS (local oxidation of silicon) process may also be used, which will not be limited here. The first gate stack 124 and the second gate stack 125 each include a gate metal layer and a gate dielectric layer.

According to embodiments of the present disclosure, the channel portion 122 includes one of monocrystalline silicon, SiGe (silicon germanium), an III-V material, or an oxide.

According to embodiments of the present disclosure, the channel portion 122 includes a first portion located between the first gate stack 124 and the second gate stack 125, a second portion located between the second gate stack 124 and the first source/drain portion 121, and a third portion located between the second gate stack 124 and the second source/drain portion 123. The first portion of the channel portion 122 extends in the vertical direction, and the second portion and the third portion of the channel portion 122 extend in a second horizontal direction intersecting the first horizontal direction. Respective channel portions 122 of the first field-effect transistor 120 and the second field-effect transistor 130 are each U-shaped, and have openings that are opposite to each other or reversed. In the vertical direction, an end portion of the second portion of the channel portion 122 in the first horizontal direction and an end portion of the third portion of the channel portion 122 in the first horizontal direction are aligned with a sidewall of the second gate stack 124 in the first horizontal direction. Respective first gate stacks 124 or respective second gate stacks 125 of the first field-effect transistor 120 and the second field-effect transistor 130 are opposite to each other.

According to embodiments of the present disclosure, when different operating voltages are applied to the first gate stack and the second gate stack, a multi-threshold voltage regulation of the semiconductor device is achieved. According to embodiments of the present disclosure, the first field-effect transistor and the second field-effect transistor that are mirror-symmetrical relative to the first plane on the substrate each include the first gate stack and the second gate stack separated by the channel portion, so that the multi-threshold voltage regulation of the semiconductor device may be achieved by adjusting respective operating voltages of the first gate stack and the second gate stack. Channel regions and lengths controlled by the first gate stack and the second gate stack are different, so a more comprehensive and multi-directional voltage regulation of the device may be achieved. In addition, a gate electrode in one of the gate stacks may be set as a back gate, so that a back-gate regulation may be performed on the device, and a threshold voltage may be controlled.

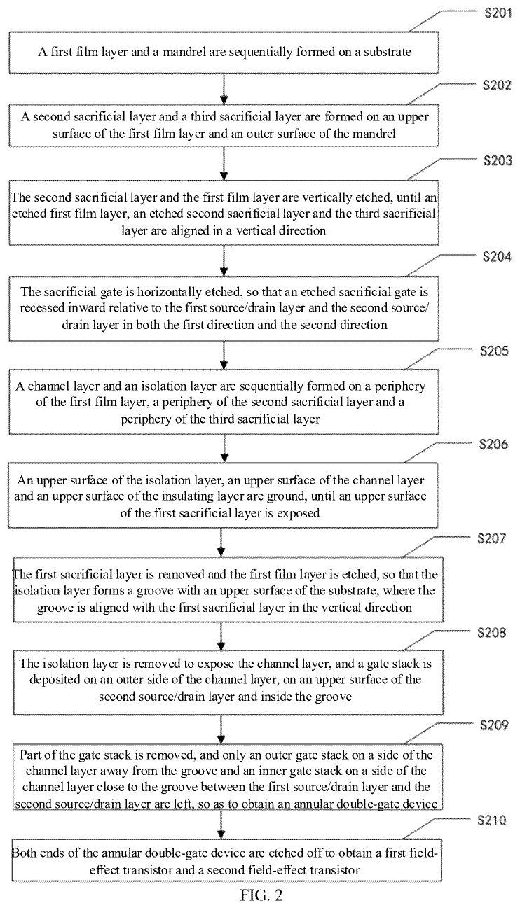

FIG. 2 schematically shows a flowchart of a method of manufacturing a semiconductor device according to embodiments of the present disclosure.

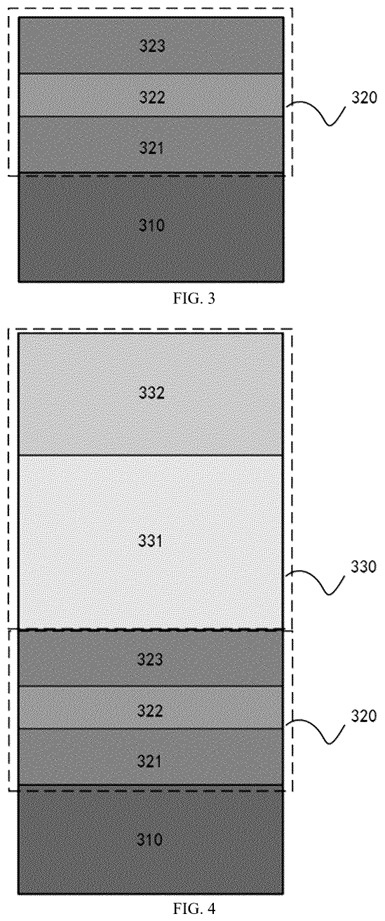

FIG. 3 to FIG. 18 schematically show cross-sectional views of structures obtained after performing part of processes in the method shown in FIG. 2.

As shown in FIG. 2, the method includes operations S201 to S210.

In the operation S201, a first film layer and a mandrel are sequentially formed on a substrate.

As shown in FIG. 3 to FIG. 4, a first film layer 320 and a second film layer 330 stacked on the first film layer 320 may be formed on a substrate 310 by using an epitaxial process. The first film layer 320 includes a first source/drain layer 321, a sacrificial gate 322 on the first source/drain layer 321 and a second source/drain layer 323 on the sacrificial gate 322. The second film layer 330 may be a Si/GeSi/Si stack, and the second film layer 330 includes a first sacrificial layer 331 and an insulating layer 332 located on the first sacrificial layer 331.

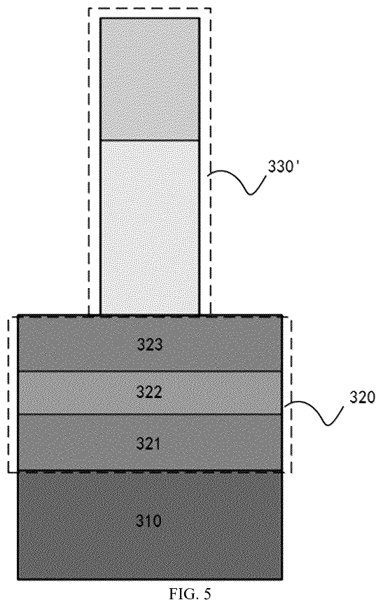

As shown in FIG. 5, the second film layer 330 is vertically etched, so that an etched second film layer 330 is recessed inward relative to the first film layer 320 in both a first horizontal direction and a second horizontal direction intersecting the first horizontal direction, so as to obtain a mandrel 330′. Here, for convenience, a hard mask structure that may be used in a patterning process is not shown in the figure.

In the operation S202, a second sacrificial layer and a third sacrificial layer are formed on an upper surface of the first film layer and an outer surface of the mandrel.

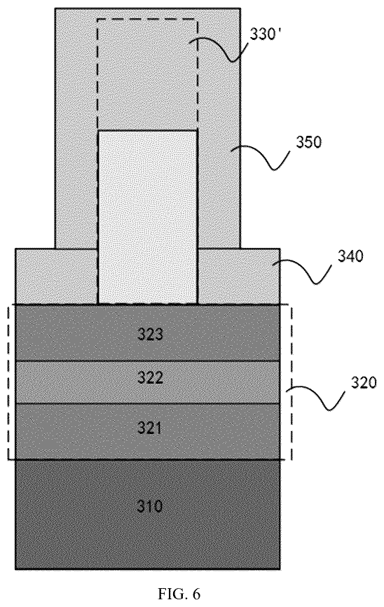

As shown in FIG. 6, a second sacrificial layer 340 and a third sacrificial layer 350 are deposited on an upper surface of the first film layer 320 and an outer surface of the mandrel 330′. Materials of the second sacrificial layer 340 and the third sacrificial layer 350 may both be silicon dioxide, and the third sacrificial layer 350 is recessed inward relative to the second sacrificial layer 340 in both the first horizontal direction and the second horizontal direction.

In the operation S203, the second sacrificial layer and the first film layer are vertically etched, until an etched first film layer, an etched second sacrificial layer and the third sacrificial layer are aligned in a vertical direction.

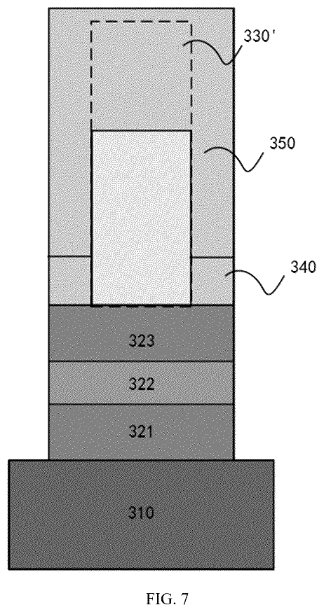

As shown in FIG. 7, the second sacrificial layer 340 and the first film layer 320 may be vertically etched by using a dry etching process, until an etched first film layer 320, an etched second sacrificial layer 340 and the third sacrificial layer 350 are aligned in the vertical direction. A material of the insulating layer 332 is the same as a material of the second sacrificial layer 340 and a material of the third sacrificial layer 350 and is different from a material of the first sacrificial layer 331, so that an etching rate of the insulating layer 332 is greater than an etching rate of the first sacrificial layer 331.

In the operation S204, the sacrificial gate is horizontally etched, so that an etched sacrificial gate is recessed inward relative to the first source/drain layer and the second source/drain layer in both the first horizontal direction and the second horizontal direction.

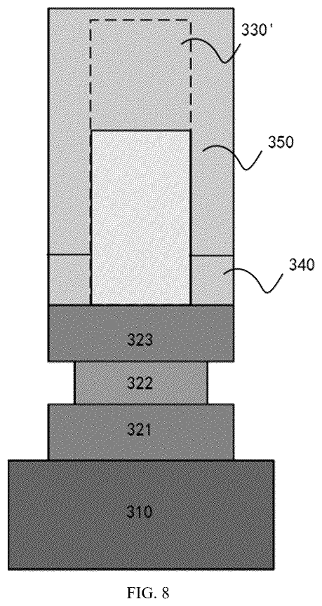

As shown in FIG. 8, the sacrificial gate 322 is horizontally etched, so that an etched sacrificial gate 322 is recessed inward relative to the first source/drain layer 321 and the second source/drain layer 323 in both the first horizontal direction and the second horizontal direction.

In the operation S205, a channel layer and an isolation layer are sequentially formed on a periphery of the first film layer, a periphery of the second sacrificial layer and a periphery of the third sacrificial layer.

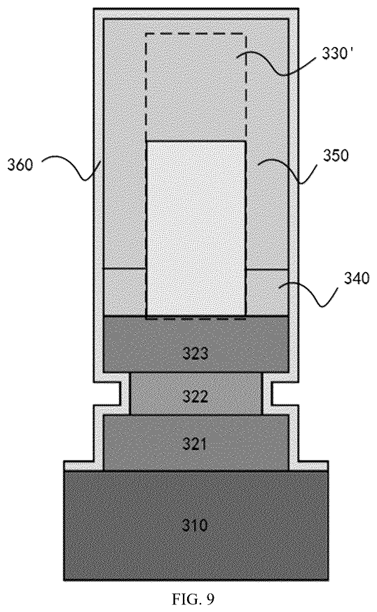

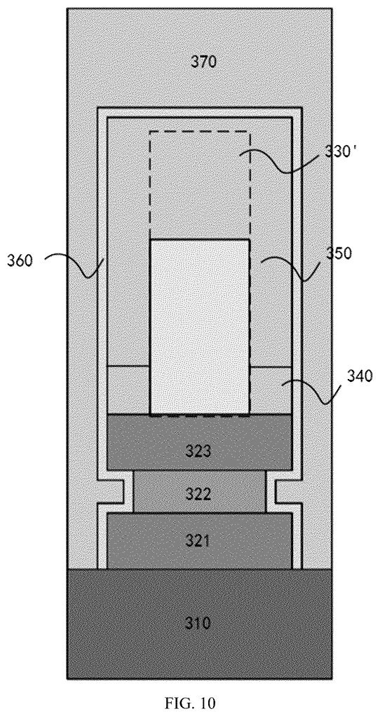

As shown in FIG. 9 and FIG. 10, a channel layer 360 is deposited on a periphery of a previously obtained structure, and an isolation layer 370 is deposited on the channel layer 360.

According to embodiments of the present disclosure, when Si or SiGe or an III-V material is selected as the channel layer 360, the channel layer may be formed by an epitaxial process; when an oxide is selected as the channel layer 360, the channel layer may be formed by an atomic layer deposition or a physical vapor deposition.

In the operation S206, an upper surface of the isolation layer, an upper surface of the channel layer and an upper surface of the insulating layer are ground, until an upper surface of the first sacrificial layer is exposed.

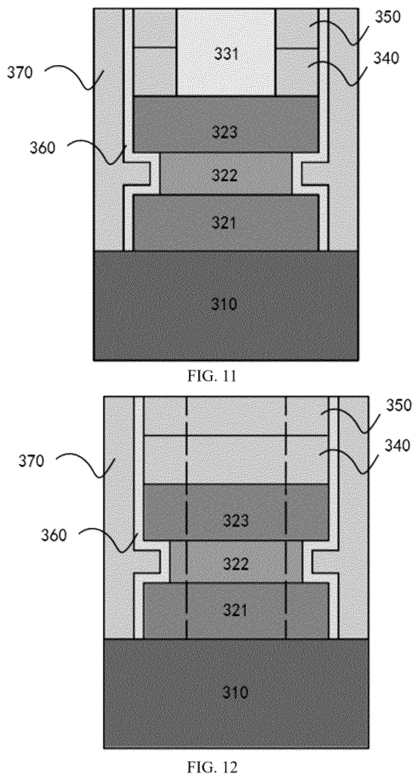

As shown in FIG. 11, the structure shown in FIG. 10 may be ground from top to bottom by using a chemical mechanical polishing process, until an upper surface of the first sacrificial layer 331 is exposed.

In the operation S207, the first sacrificial layer is removed and the first film layer is etched, so that the isolation layer forms a groove with an upper surface of the substrate, where the groove is aligned with the first sacrificial layer in the vertical direction.

As shown in FIG. 12, the first sacrificial layer 331 is removed, and the first film layer 320 is etched according to a shape of the first sacrificial layer 331, so that the isolation layer 370 forms a groove with the upper surface of the substrate.

In the operation S208, the isolation layer is removed to expose the channel layer, and a gate stack is deposited on an outer side of the channel layer, on an upper surface of the second source/drain layer and inside the groove.

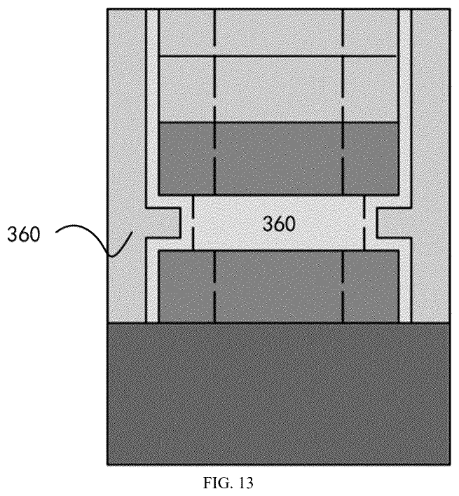

As shown in FIG. 13, the sacrificial gate 322 is removed to expose the channel layer 360 in the groove.

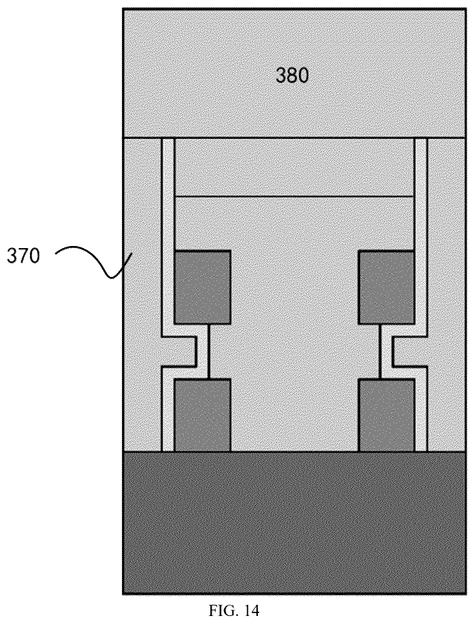

As shown in FIG. 14, an outer isolation layer 390 is deposited on an upper surface of the structure shown in FIG. 13 and inside the groove.

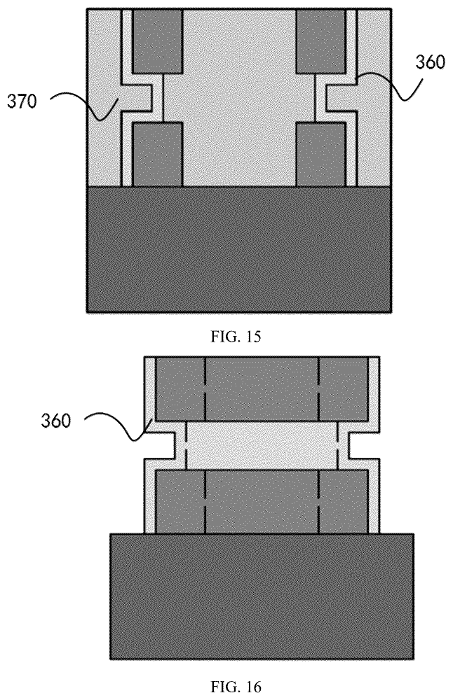

As shown in FIG. 15, the structure shown in FIG. 14 may be ground from top to bottom by using a chemical mechanical polishing process, until an upper surface of the second source/drain layer 323 is exposed.

As shown in FIG. 16, the isolation layer 370 may be removed by using a wet etching process, so that the whole channel layer 360 is exposed.

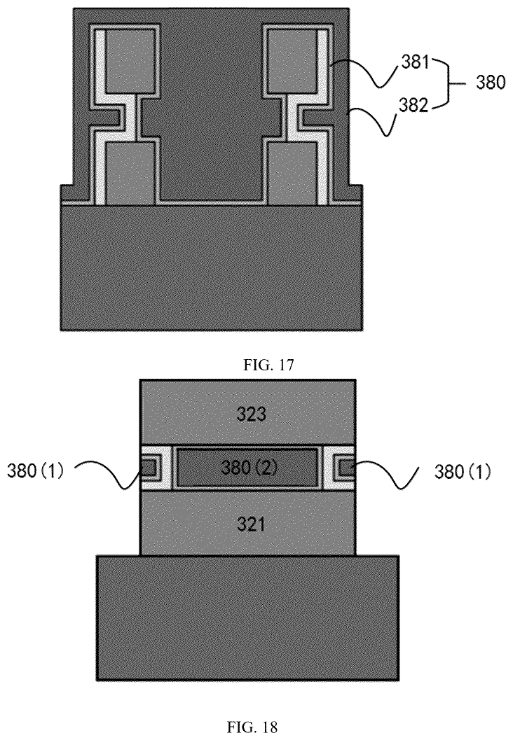

As shown in FIG. 17, a gate stack 380 is deposited on an outer side of the channel layer 360, on an upper surface of the second source/drain layer 323 and inside the groove. The gate stack 380 includes a gate dielectric layer 381 and a gate metal layer 382.

In the operation S209, part of the gate stack is removed, and only an outer gate stack on a side of the channel layer away from the groove and an inner gate stack on a side of the channel layer close to the groove between the first source/drain layer and the second source/drain layer are left, so as to obtain an annular double-gate device.

As shown in FIG. 18, part of the gate stack 380 except for an outer gate stack 380(1) on a side of the channel layer 360 away from the groove and an inner gate stack 380(2) on a side of the channel layer 360 close to the groove between the first source/drain layer 321 and the second source/drain layer 323 is etched off, so as to obtain the annular double-gate device.

In the operation S210, both ends of the annular double-gate device are etched off to obtain a first field-effect transistor and a second field-effect transistor.

According to embodiments of the present disclosure, an etched inner gate stack is used as a first gate stack of the first field-effect transistor and the second field-effect transistor, an etched outer gate stack is used as a second gate stack of the first field-effect transistor and the second field-effect transistor, the first source/drain layer is used as a first source/drain portion of the first field-effect transistor and the second field-effect transistor, and the second source/drain layer is used as a second source/drain portion of the first field-effect transistor and the second field-effect transistor.

In the above-mentioned descriptions, the technical details such as patterning and etching of each layer have not been described in detail. However, those skilled in the art should understand that various technical means may be used to form layers, regions, etc. of desired shapes. In addition, in order to form the same structure, those skilled in the art may further design a method that is not exactly the same as the method described above. In addition, although the various embodiments have been described above separately, this does not mean that the measures in the various embodiments may not be advantageously used in combination.

Embodiments of the present disclosure have been described above. However, the embodiments are for illustrative purposes only, and are not intended to limit the scope of the present disclosure. Although embodiments are described above separately, this does not mean that the measures in embodiments may not be advantageously used in combination. Without departing from the scope of the present disclosure, those skilled in the art may make various substitutions and modifications, and these substitutions and modifications should all fall within the scope of the present disclosure.

What is claimed is:

1. A semiconductor device, comprising:
a substrate; and
a first field-effect transistor and a second field-effect transistor that are respectively stacked on the substrate and are mirror-symmetrical relative to a first plane extending in a vertical direction and a first horizontal direction, wherein the first field-effect transistor and the second field-effect transistor each comprise:
a first source/drain portion, a channel portion and a second source/drain portion that are sequentially stacked on the substrate, and a gate stack located on two opposite sides of the channel portion in the first horizontal direction, wherein the gate stack comprises a first gate stack and a second gate stack, the first gate stack is located on a side of the channel portion close to the first plane, and the second gate stack is located on a side of the channel portion away from the first plane and at least partially surrounded by the channel portion in the first horizontal direction.

2. The device according to claim 1, wherein the channel portion comprises a first portion located between the first gate stack and the second gate stack, a second portion located between the second gate stack and the first source/drain portion, and a third portion located between the second gate stack and the second source/drain portion.

3. The device according to claim 2, wherein the first portion of the channel portion extends in the vertical direction, and the second portion and the third portion of the channel portion extend in a second horizontal direction intersecting the first horizontal direction.

4. The device according to claim 1, wherein respective channel portions of the first field-effect transistor and the second field-effect transistor are each U-shaped, and have openings that are opposite to each other or reversed.

5. The device according to claim 2, wherein in the vertical direction, an end portion of the second portion of the channel portion in the first horizontal direction and an end portion of the third portion of the channel portion in the first horizontal direction are aligned with a sidewall of the second gate stack in the first horizontal direction.

6. The device according to claim 1, wherein respective first gate stacks or respective second gate stacks of the first field-effect transistor and the second field-effect transistor are opposite to each other.

7. The device according to claim 1, wherein when different operating voltages are applied to the first gate stack and the second gate stack, a multi-threshold voltage regulation of the semiconductor device is achieved.

8. A method of manufacturing a semiconductor device, comprising:
sequentially forming a first film layer and a mandrel on a substrate, wherein the first film layer comprises a first source/drain layer, a sacrificial gate on the first source/drain layer and a second source/drain layer on the sacrificial gate, the mandrel comprises a first sacrificial layer and an insulating layer located on the first sacrificial layer, and the mandrel is recessed inward relative to the first film layer in both a first horizontal direction and a second horizontal direction intersecting the first horizontal direction;
forming a second sacrificial layer and a third sacrificial layer on an upper surface of the first film layer and an outer surface of the mandrel, wherein the third sacrificial layer is recessed inward relative to the second sacrificial layer in both the first horizontal direction and the second horizontal direction;
vertically etching the second sacrificial layer and the first film layer, until an etched first film layer, an etched second sacrificial layer and the third sacrificial layer are aligned in a vertical direction;
horizontally etching the sacrificial gate, so that an etched sacrificial gate is recessed inward relative to the first source/drain layer and the second source/drain layer in both the first horizontal direction and the second horizontal direction;
sequentially forming a channel layer and an isolation layer on a periphery of the first film layer, a periphery of the second sacrificial layer and a periphery of the third sacrificial layer;
grinding an upper surface of the isolation layer, an upper surface of the channel layer and an upper surface of the insulating layer, until an upper surface of the first sacrificial layer is exposed;
removing the first sacrificial layer and etching the first film layer, so that the isolation layer forms a groove with an upper surface of the substrate, wherein the groove is aligned with the first sacrificial layer in the vertical direction;
removing the isolation layer to expose the channel layer, and depositing a gate stack on an outer side of the channel layer, on an upper surface of the second source/drain layer and inside the groove;
removing part of the gate stack, and leaving only an outer gate stack on a side of the channel layer away from the groove and an inner gate stack on a side of the channel layer close to the groove between the first source/drain layer and the second source/drain layer, so as to obtain an annular double-gate device; and
etching off both ends of the annular double-gate device to obtain a first field-effect transistor and a second field-effect transistor, wherein an etched inner gate stack is used as a first gate stack of the first field-effect transistor and the second field-effect transistor, and an etched outer gate stack is used as a second gate stack of the first field-effect transistor and the second field-effect transistor.

9. The method according to claim 8, wherein the sequentially forming a first film layer and a mandrel on a substrate comprises:
forming, on the substrate, the first film layer and a second film layer stacked on the first film layer, wherein the second film layer comprises the first sacrificial layer and the insulating layer located on the first sacrificial layer; and
vertically etching the second film layer to obtain the mandrel.

10. The method according to claim 8, wherein a material of the insulating layer is the same as a material of the second sacrificial layer and a material of the third sacrificial layer and is different from a material of the first sacrificial layer, so that an etching rate of the insulating layer is greater than an etching rate of the first sacrificial layer.
